(19) United States
(12) Patent Application Publication
(10) Pub. No.: US 2009/0253080 A1
(43) Pub. Date: Oct. 8, 2009

(54) Photoresist Image-Forming Process Using Double Patterning

(76) Inventors: Ralph R. Dammel, Flemington, NJ (US); David Abdallah, Bernardsville, NJ (US); Eric Alemy, Franklin, NJ (US); Munirathna Padmanaban, Bridgewater, NJ (US)

Correspondence Address: SANGYA JAIN;AZ ELECTRONIC MATERIALS USA CORP., 70 MEISTER AVENUE, SOMERVILLE, NJ, 08876, US

(21) Appl. No.: 12/061,061

(22) Filed: Apr. 2, 2008

(51) Int. Cl. G03F 7/30

(52) U.S. Cl. 430/324

(57) ABSTRACT

A process for forming a photoresist pattern on a device, comprising; a) forming a layer of first photoresist on a substrate from a first photoresist composition; b) imagewise exposing the first photoresist; c) developing the first photoresist to form a first photoresist pattern; d) treating the first photoresist pattern with a hardening compound comprising at least 2 amino (NH₂) groups, thereby forming a hardened first photoresist pattern; e) forming a second photoresist layer on the region of the substrate including the hardened first photoresist pattern from a second photoresist composition; f) imagewise exposing the second photoresist; and, g) developing the imagewise exposed second photoresist to form a second photoresist pattern between the first photoresist pattern, thereby providing a double photoresist pattern.

### FIELD OF INVENTION

The present invention relates to a process for forming fine photoresist patterns on a device using double imagewise patterning.

### DESCRIPTION

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon wafers used for making integrated circuits. The coated substrate is then baked to evaporate any solvent in the photoresist composition and to fix the coating onto the substrate. The photoresist coated on the substrate is next subjected to an image-wise exposure to radiation.

The radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is optionally baked, and then treated with a developer solution to dissolve and remove either the radiation exposed (positive photoresist) or the unexposed areas of the photoresist (negative photoresist).

Positive working photoresists when they are exposed image-wise to radiation have those areas of the photoresist composition exposed to the radiation become more soluble to the developer solution while those areas not exposed remain relatively insoluble to the developer solution. Thus, treatment of an exposed positive-working photoresist with the developer causes removal of the exposed areas of the coating and the formation of a positive image in the photoresist coating. Again, a desired portion of the underlying surface is uncovered.

Negative working photoresists when they are exposed image-wise to radiation, have those areas of the photoresist composition exposed to the radiation become insoluble to the developer solution while those areas not exposed remain relatively soluble to the developer solution. Thus, treatment of a non-exposed negative-working photoresist with the developer causes removal of the unexposed areas of the coating and the formation of a negative image in the photoresist coating. Again, a desired portion of the underlying surface is uncovered.

Photoresist resolution is defined as the smallest feature which the photoresist composition can transfer from the photomask to the substrate with a high degree of image edge acuity after exposure and development. In many leading edge manufacturing applications today, photoresist resolution on the order of less than 100 nm is necessary. In addition, it is almost always desirable that the developed photoresist wall profiles be near vertical relative to the substrate. Such demarcations between developed and undeveloped areas of the photoresist coating translate into accurate pattern transfer of the mask image onto the substrate. This becomes even more critical as the push toward miniaturization reduces the critical dimensions on the devices.

Photoresists sensitive to short wavelengths, between about 100 nm and about 300 nm, are often used where subhalfmicron geometries are required. Particularly preferred are deep uv photoresists sensitive at below 200 nm, e.g. 193 nm and 157 nm, comprising non-aromatic polymers, a photoacid generator, optionally a dissolution inhibitor, base quencher and solvent.

High resolution, chemically amplified, deep ultraviolet (100-300 nm) positive and negative tone photoresists are available for patterning images with less than quarter micron geometries.

The primary function of a photoresist is to accurately replicate the image intensity profile projected into it by the exposure tool. This becomes increasingly difficult as the distance between features on the mask shrinks since the image intensity contrast decreases and eventually vanishes when the distance falls below the diffraction limit of the exposure tool. In terms of device density, it is the feature pitch which is of primary importance since it relates to how close features can be packed. In order to form patterns in a photoresist film at pitches less than 0.5λ/NA (λ is the wavelength of the exposing radiation and NA is the numerical aperture of the lens for exposure), one technique that has been used is double patterning. Double patterning provides a method for increasing the density of photoresist patterns in a microelectronic device. Typically in double patterning a first photoresist pattern is defined on a substrate at pitches greater than 0.5λ/NA and then in another step a second photoresist pattern is defined at the same pitch as the first pattern between the first photoresist pattern. Both images are transferred simultaneous to the substrate with the resulting pitch that is half of the single exposures. Dual patterning approaches available today are based on forming two hard mask images via two pattern transfer processes. Double patterning allows for the photoresist features to be present in close proximity to each other, typically through pitch splitting.

In order to be able to coat a second photoresist over the patterned first photoresist, the first photoresist pattern is typically stabilized/hardened or frozen so that there is no intermixing with the second photoresist or deformation of the first photoresist pattern. Various types of double patterning methods are known which stabilize or freeze the first photoresist pattern prior to coating the second photoresist over the first photoresist pattern, such as thermally curing, UV curing, e-beam curing and ion implantation of the first photoresist pattern. Thermal curing can only be used for photoresists where the glass transition temperature of the photoresist polymer is higher than the stabilization temperature, and such a process is not useful for all photoresists. Stabilization of the first photoresist pattern prevents intermixing between the first photoresist pattern and the second photoresist layer, which allows for good lithographic images to be formed on the substrate. Thus there is a need for a process of stabilizing the first photoresist pattern which is useful for a wide range of photoresists.

The present invention relates to a double patterning process comprising a hardening treatment for the first photoresist pattern to increase its resistance to dissolution in the second photoresist solvent and to an aqueous alkaline developer, and also prevent intermixing with the second photoresist.

### SUMMARY OF THE INVENTION

The present invention relates to a process for forming a photoresist pattern on a device, comprising; a) forming a layer of first photoresist on a substrate from a first photoresist composition, b) imagewise exposing the first photoresist; c) developing the first photoresist to form a first photoresist pattern; d) treating the first photoresist pattern with a hardening compound comprising at least 2 amino (NH₂) groups, thereby forming a hardened first photoresist pattern; e) forming a second photoresist layer on the region of the substrate including the hardened first photoresist pattern from a second photoresist composition; f) imagewise exposing the second photoresist; and, g) developing the imagewise exposed second photoresist to form a second photoresist pattern between the first photoresist pattern, thereby providing a double photoresist pattern.

The process further includes a hardening compound having structure (1),

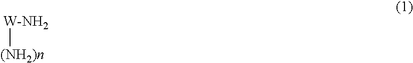

where, W is a C₁-C₈ alkylene, and n is 1-3.

### BRIEF DESCRIPTION OF THE DRAWINGS

FIG. 1 shows a process for double imagewise patterning.

FIG. 2 shows a design of a photoresist hardening chamber.

### DETAILED DESCRIPTION OF THE INVENTION

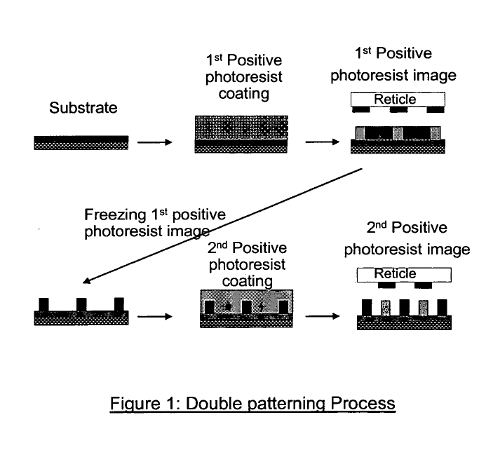

The present invention relates to a process for imaging fine patterns on a microelectronic device using double imagewise patterning of two photoresist layers. The process comprises patterning of a first photoresist layer followed by a second imagewise (using a mask or reticle) photoresist patterning step which forms a pattern interdigitated to the first pattern. Interdigitated refers to an alternating pattern of the second pattern placed between the first pattern. The double patterning step allows for an increase in pattern density as compared to a single patterning step. The inventive process is illustrated in FIG. 1, where the process comprises, a) forming a layer of first photoresist on a substrate from a first photoresist composition; b) imagewise exposing the first photoresist; c) developing the first photoresist to form a first photoresist pattern; d) treating or freezing the first photoresist pattern with a hardening compound comprising at least 2 amino (NH₂) groups, thereby forming a hardened first photoresist pattern; e) forming a second photoresist layer on the region of the substrate including the hardened first photoresist pattern from a second photoresist composition; f) imagewise exposing the second photoresist; and, g) developing the second photoresist pattern between the first photoresist pattern, thereby forming a double photoresist pattern. The second pattern is interdigitated to the first pattern, that is an alternating first and second pattern is formed.

The first layer of photoresist is imaged on a substrate using known techniques of forming a layer of a photoresist from a photoresist composition. The photoresist may be positive acting or negative acting. The photoresist comprises a polymer, photoacid generator a solvent, and may further comprise additives such as basic qenchers, surfactants, dyes and crosslinkers. An edge bead remover may be applied after the coating steps to clean the edges of the substrate using processes well known in the art. The photoresist layer is softbaked to remove the photoresist solvent. The photoresist layer is then imagewise exposed through a mask or reticle, optionally post exposure baked, and then developed using an aqueous alkaline developer. After the coating process, the photoresist can be imagewise exposed using any imaging radiation, such as those ranging from 13 nm to 450 nm. Typical radiation sources are 157 nm, 193 nm, 248 nm, 365 nm and 436 nm. The exposure may be done using typical dry exposure or may be done using immersion lithography. The exposed photoresist is then developed in an aqueous developer to form the photoresist pattern. The developer is preferably an aqueous alkaline solution comprising, for example, tetramethyl ammonium hydroxide. An optional heating step can be incorporated into the process prior to development and after exposure. The exact conditions of coating, baking, imaging and developing are determined by the photoresist used.

The substrates over which the photoresist coating is formed can be any of those typically used in the semiconductor industry. Suitable substrates include, without limitation, silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/N compounds. The substrate may comprise any number of layers made from the materials described above. These substrates may further have a single or multiple coating of antireflective coatings prior to the coating of the photoresist layer. The coatings may be inorganic, organic or mixture of these. The coatings may be siloxane or silicone on top of a high carbon content antireflective coating. Any types of antireflective coatings are known in the art may be used.

The present process is particularly suited to deep ultraviolet exposure. Typically chemically amplified photoresists are used. They may be negative or positive. To date, there are several major deep ultraviolet (uv) exposure technologies that have provided significant advancement in miniaturization, and these are radiation of 248 nm, 193 nm, 157 and 13.5 nm. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure below 200 nm require non-aromatic polymers since aromatics are opaque at this wavelength. U.S. Pat. No. 5,843,624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures. U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference.

Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587, and U.S. Pat. No. 6,849,377) using either metal catalyzed or radical polymerization. Generally, these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (Shun-ichi K Iodama et al Advances in Resist Technology and Processing XIX, Proceedings of SPIE Vol. 4690 p 76 2002; U.S. Pat. No. 6,818,258) or copolymerization of a fluorodiene with an olefin (U.S. Pat. No. 6,916,590). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art. Photoresists sensitive to 365 nm and 436 nm may also be used. At the present time 193 nm photoresists are preferred.

The solid components of the photoresist composition are mixed with a solvent or mixtures of solvents that dissolve the solid components of the photoresist. Suitable solvents for the photoresist may include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate; carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; a ketal or acetal like 1,3 dioxaine and diethoxypropane; lactones such as butyrolactone; an amide derivative such as dimethylacetamide or dimethylformamide, anisole, and mixtures thereof. Typical solvents for photoresist, used as mixtures or alone, that can be used, without limitation, are propylene glycol monomethyl ether acetate (PGMEA), propylene gycol monomethyl ether (PGME), and ethyl lactate (EL), 2-heptanone, cyclopentanone, cyclohexanone, and gamma but rolactone, but PGME, PGMEA and EL or mixtures thereof are preferred. Solvents with a lower degree of toxicity, good coating and solubility properties are generally preferred.

In one embodiment of the process a photoresist sensitive to 193 nm is used. The photoresist comprises a polymer, a photoacid generator, and a solvent. The polymer is an (meth)acrylate polymer which is insoluble in an aqueous alkaline developer. Such polymers may comprise units derived from the polymerization of monomers such as alicyclic (meth)acrylates, mevalonic lactone methacrylate, 2-methyl-2-adamantyl methacrylate, 2-adamantyl methacrylate (AdMA), 2-methyl-2-adamantyl acrylate (MAdA), 2-ethyl-2-adamantyl methacrylate (EAdMA), 3,5-dimethyl-7-hydroxy adamantyl methacrylate (DMHAdMA), isoadamantyl methacrylate, hydroxy-1-methacryloxyadamatane (HAdMA; for example, hydroxy at the 3-position), hydroxy-1-adamantyl acrylate (HADA; for example, hydroxy at the 3-position), ethylcyclopentylacrylate (ECPA), ethylcyclopentylmethacrylate (ECPMA), tricyclo[5,2,1,0^{2,6}]deca-8-yl methacrylate (TCDMA), 3,5-dihydroxy-1-methacryloxyadamantane (DHAdMA), β-methacryloxy-γ-butyrolactone, α- or β-gamma-butyrolactone methacrylate (either α- or β-GBLMA), 5-methacryloyloxy-2,6-norbornanecarbolactone (MNBL), 5-acryloyloxy-2,6-norbornanecarbolactone (ANBL), isobutyl methacrylate (IBMA), α-gamma-butyrolactone acrylate (α-GBLA), spirolactone (meth)acrylate, oxytricyclodecane (meth)acrylate, adamantane lactone (meth)acrylate, and α-methacryloxy-γ-butyrolactone, among others. Examples of polymers formed with these monomers include poly(2-methyl-2-adamantyl methacrylate-co-2-ethyl-2-adamantyl methacrylate-co-3-hydroxy-1-methacryloxyadamantane-co-α-gamma-butyrolactone methacrylate); poly(2-ethyl-2-adamantyl methacrylate-co-3-hydroxy-1-methacryloxyadamantane-co-β-gamma-butyrolactone methacrylate); poly(2-methyl-2-adamantyl methacrylate-co-3-hydroxy-1-methacryloxyadamantane-co-β-gamma-butyrolactone methacrylate); poly(t-butyl norbornene carboxylate-co-maleic anhydride-co-2-methyl-2-adamantyl methacrylate-co-1-gamma-butyrolactone methacrylate-co-methacryloyloxy norbornene methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-ylmethacrylate); poly(2-ethyl-2-adamantyl methacrylate-co-3-hydroxy-1-adamantyl acrylate-co-β-gamma-butyrolactone methacrylate); poly(2-ethyl-2-adamantyl methacrylate-co-3-hydroxy-1-adamantyl acrylate-co-α-gamma-butyrolactone methacrylate-co-tricyclo[5,2,1,0^{2,6}]deca-8-yl methacrylate); poly(2-methyl-2-adamantyl methacrylate-co-3,5-dihydroxy-1-methacryloxyadamantane-co-α-gamma-butyrolactone methacrylate); poly(2-methyl-2-adamantyl methacrylate-co-5,5-dimethyl-7-hydroxy adamantyl methacrylate-co-α-gamma-butyrolactone methacrylate); poly(2-methyl-2-adamantyl acrylate-co-3-hydroxy-1-methacryloxyadamantane-co-α-gamma-butyrolactone methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-ylmethacrylate); poly(2-methyl-2-adamantyl methacrylate-co-β-gamma-butyrolactone methacrylate-co-3-hydroxy-1-methacryloxyadamantane-co-ethylcyclopentylacrylate); poly(2-methyl-2-adamantyl methacrylate-co-3-hydroxy-1-adamantyl acrylate-co-α-gamma-butyrolactone methacrylate); poly(2-methyl-2-adamantyl methacrylate-co-3-hydroxy-1-methacryloxyadamantane-co-α-gamma-butyrolactone methacrylate-co-2-ethyl-2-adamantyl methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-yl methacrylate); poly(2-methyl-2-adamantyl methacylate-co-2-ethyl-2-adamantyl methacrylate-co-β-gamma-butyrolactone methacrylate-co-3-hydroxy-1-methacryloxyadamantane); poly(2-methyl-2-adamantyl methacrylate-co-2-ethyl-2-adamantyl methacrylate-co-α-gamma-butyrolactone methacrylate-co-3-hydroxy-1-methacryloxyadamantane); poly(2-methyl-2-adamantyl methacrylate-co-methacryloyloxy norbornene methacrylate-co-β-gamma-butyrolactone methacrylate); poly(ethylcyclopentylmethacrylate-co-2-ethyl-2-adamantyl methacrylate-co-α-gamma-butyrolactone acrylate); poly(2-ethyl-2-adamantyl methacrylate-co-3-hydroxy-1-adamantyl acrylate-co-isobutyl methacrylate-co-α-gamma-butyrolactone acrylate); poly(2-methyl-2-adamantyl methacrylate-co-β-gamma-butyrolactone methacrylate-co-3-hydroxy-1-adamantyl acrylate-co-tricyclo[5,2,1,0^{2,6}]deca-8-yl methacrylate); poly(2-ethyl-2-adamantyl methacrylate-co-3-hydroxy-1-adamantyl acrylate-co-α-gamma-butyrolactone acrylate); poly(2-methyl-2-adamantyl methacrylate-co-β gamma-butyrolactone methacrylate-co-2-adamantyl methacrylate-co-3-hydroxy-1-methacryloxyadamatane); poly(2-methyl-2-adamantyl methacrylate-co-methacryloyloxy norbornene methacrylate-co-β-gamma-butyrolactone methacrylate-co-2-adamantyl methacrylate-co-3-hydroxy-1-methacryloxyadamatane); poly(2-methyl-2-adamantyl methacrylate-co-methacryloyloxy norbornene methacrylate-co-tricyclo[5,2,1,0^{2,6}]deca-8-yl methacrylate-co-3-hydroxy-1-methacryloxyadamatane-co-α-gamma-butyrolactone methacrylate); poly(2-ethyl-2-adamantyl meth acrylate-co-3-hydroxy-1-adamantyl acrylate-co-tricyclo[5,2,1,0^{2,6}]deca-8-yl methacrylate-co-α-gam ma-butyrolactone methacrylate); poly(2-ethyl-2-adamantyl methacrylate-co-3-hydroxy-1-adamantyl acrylate-co-α-gamma-butyrolactone acrylate); poly(2-methyl-2-adamantyl methacrylate-co-3-hydroxy-1-methacryloxyadamatane-co-α-gamma-butyrolactone methacrylate-co-2-ethyl-2-adamantyl-co-methacrylate); poly(2-ethyl-2-adamantyl methacrylate-co-3-hydroxy-1-adamantyl acrylate-co-α-gamma-butyrolactone methacrylate-co-tricyclo[5,2,1,0^{2,6}]deca-8-ylmethacrylate); poly(2-ethyl-2-adamantyl methacrylate-co-3-hydroxy-1-adamantyl acrylate-co-α-gamma-butyrolactone methacrylate); poly(2-methyl-2-adamantyl methacrylate-co-3-hydroxy-1-adamantyl acrylate-co-5-acryloyloxy-2,6-norbornanecarbolactone); poly(2-ethyl-2-adamantyl methacrylate-co-3-hydroxy-1-adamantyl acrylate-co-α-gamma-butyrolactone methacrylate-co-α-gamma-butyrolactone acrylate); poly(2-ethyl-2-adamantyl methacrylate-co-3-hydroxy-1-adamantyl acrylate-co-α-gamma-butyrolactone methacrylate-co-2-adamantyl methacrylate); and poly(2-ethyl-2-adamantyl methacrylate-co-3-hydroxy-1-adamantyl acrylate-co-α-gamma-butyrolactone acrylate-co-tricyclo[5,2,1,02,6]deca-8-yl methacrylate).

The photoresist may further comprise additives such as basic qenchers, surfactants, dyes, crosslinkers, etc. Useful photoresists are further exemplified and incorporated by reference in US application with Ser. No. 11/834,490 and US publication number US 2007/0015084.

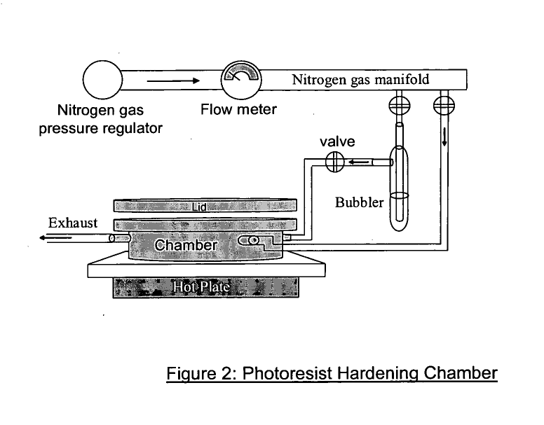

After the formation of the first photoresist pattern, the pattern is treated with a hardening compound to harden the photoresist so that the pattern becomes insoluble in the solvent of the second photoresist composition. In cases where the photoresist polymer has a glass transition temperature (Tg) lower than the hardening temperature of the photoresist alone, a hardening compound treatment is very useful, since lower temperatures than the Tg of the photoresist polymer can be used to harden the photoresist pattern. Photoresists comprising acrylate polymers are useful for hardening treatment of the present invention, since the Tg is lower than 200° C. In the present invention the hardening is done with a hardening amino compound comprising at least 2 amino (—NH₂) groups and simultaneously heating the photoresist pattern, thereby forming a hardened first photoresist pattern. Although not being bound by the theory, it is believed that the amino compound diffuses through the first photoresist pattern and in the presence of heat crosslinks the photoresist, thereby forming a hardened or frozen pattern. The pattern becomes insoluble in the solvent of the second photoresist composition. The hardening treatment may be done on a hot plate with a chamber or an enclosed oven, with the vapor of the hardening compound. The hardening of the first photoresist pattern may be done on a hotplate in an enclosed chamber where the amino compound is introduced in a vaporized form with a carrier gas like nitrogen, and the chamber further comprises a heating source to heat the patterned substrate in an enclosed atmosphere. In one case, the chamber comprises a hotplate for supporting the substrate, an inlet to introduce the amino compound, a purging inlet and an exhaust outlet. Purging may be done with nitrogen gas. FIG. 2 shows a typical chamber for hardening the pattern. Conditions such as the type of amino compound, the temperature and time of hardening, concentration of the amino compound, flow rate of the amino compound in a chamber, etc. are optimized to give the optimum degree of hardening. The extent of hardening can be determined by soaking the hardened photoresist in the test solvent to measure the loss of the film thickness of the treated photoresist. Minimal film thickness loss is desirable, where the film thickness loss of the treated photoresist in the solvent of the second photoresist is less than 10 nm, preferably less than 8 nm and more preferably less than 5 nm. Insufficient hardening will dissolve the first photoresist. Specifically, the solvent may be selected from the solvent(s) of the photoresist described herein as an example.

The hardening compound comprises at least 2 amino (NH₂) groups, The compound may be exemplified by structure (1),

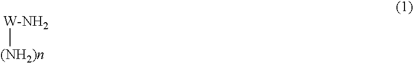

where, W is a C₁-C₈ alkylene, and n is 1-3. In one embodiment of the amino compound n=1. Alkylene may be linear or branched. Preferably alkylene is C₁-C₄. Examples of the amino compound are,

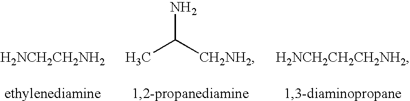

If the amino compound is used in a chamber, then a compound which can form a vapor is preferred. The amino compound may be used for hardening at temperatures in the range of about 25° C. to about 250° C., for about 30 seconds to about 20 minutes. Hardening temperature can also be around the Tg of the photoresist polymer or within 0-10° C. below the Tg. The flow rate of the compound may range from about 1 to about 10 mL/minute. The vapor pressure of the amino compound and/or its temperature can be increased to accelerate the hardening reaction. The use of the amino compound allows for lower hardening temperatures and lower hardening times than just a thermal hardening alone of the first photoresist pattern.

An additional baking step may be included after the treatment step, which can induce further crosslinking and/or densification of the pattern and also to volatilize any residual gases in the film. The baking step may range in temperature from about 190° C. to about 250° C. Densification can lead to improved pattern profiles.

After the appropriate amount of hardening of the photoresist, the first photoresist pattern may optionally be treated with a cleaning solution. Examples of cleaning solutions can be edgebead removers for photoresists such as AZ®ArF Thinner or AZ®ArF MP Thinner available commercially, or any of the photoresist solvent(s).

The first photoresist pattern is then coated to form a second layer of the second photoresist from a second photoresist composition. The second layer is the same or thicker than the thickness of the first photoresist layer to reduce topography effects. The second photoresist comprises a polymer, a photoacid generator and a solvent. The second photoresist may be the same or different than the first photoresist. The second photoresist may be chosen from any known photoresists, such as those described herein. The second photoresist is imagewise exposed and developed as described previously, and similar to the first photoresist. An edgebead remover may be used on the second photoresist layer after forming the coating. The second photoresist pattern now is defined between the first photoresist pattern and allows for the patterning of smaller and more features in the device than a single layer imaging process. The density of the photoresist pattern is increased.

The process of coating and imaging single layers of photoresists is well known to those skilled in the art and is optimized for the specific type of photoresist used. The image transfer through to the substrate from the imaged photoresist and through the antireflective coatings is carried out by dry etching in a similar manner used for etching through a single layer photoresist coating. The patterned substrate can then be dry etched with an etching gas or mixture of gases, in a suitable etch chamber to remove the exposed portions of the antireflective film, with the remaining photoresist acting as an etch mask. Various gases are known in the art for etching organic antireflective coatings, such as O₂, Cl₂, F₂ and CF₄.

Unless otherwise indicated, all numbers expressing quantities of ingredients, properties such as molecular weight, reaction conditions, and so forth used in the specification and claims are to be understood as being modified in all instances by the term “about.” Each of the documents referred to above are incorporated herein by reference in its entirety, for all purposes. The US patent application with Docket Number 2008US305 filed Apr. 1, 2008 is also incorporated herein by reference in its entirety. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

Film thicknesses measurements were performed on a Nanospec 8000 using Cauchy's material-dependent constants derived on a J. A. Woollam® VUV VASE® Spectroscopic Ellipsometer. Photoresist on bottom antireflective coatings were modeled to fit the photoresist film thickness only.

CD-SEM measurements were done on either an Applied Materials SEM Vision or NanoSEM. Cross-sectional SEM images were obtained on a Hitachi 4700.

Lithography exposures were performed on a Nikon NSR-306D (NA: 0.85) interfaced to a Tokyo Electron Clean Track 12 modified to work with 8 in wafers as well. The wafers were coated with AZ® ArF-1C5D (a bottom antireflective coating available from AZ Electronic Materials USA Corps, Somerville, N.J., USA) and baked at 200° C./60 sec to achieve 37 nm film thickness. Commercial AZ® AX2110P (available from AZ Electronic Materials USA Corps, Somerville, N.J., USA) photoresist was diluted with AZ® ArF MP Thinner (80:20 methyl-2-hydroxyisobutyrate:PGMEA) so that 90 nm film could be achieved with a coater spin rate of 1500 rpm. An attenuated PSM reticle (mask) with a large area grating composed of 1:1 90 nm Line/Space feature was overexposed to image approximately 45 nm lines using dipole illumination (0.82 outer, 0.43 inner sigma). The photoresist were soft baked at 100° C./60 s and postexposure baked (PEB) at 110° C./60 s. After PEB, the wafers were developed for 30 seconds with a surfactant-free developer, AZ® 300MIF (available from AZ Electronic Materials USA Corps, Somerville, N.J., USA), containing 2.38% tetramethyl ammonium hydroxide (TMAH).

The second exposure used the same photoresist composition and the same processing conditions as the first photoresist exposure above. No bottom antireflective coating (BARC) was necessary since the BARC from the 1st exposure remains. The same reticle was used except the field placement was incrementally shifted 12 nm (180 nm pitch/15 fields) across a row of fields so that a complete period of offsets was obtained.

### Vapor Reaction Chamber (VCR) For Freezing Photoresist Images

A schematic of the VRC is shown in Figure. The prototype freeze chamber was constructed of ½ inch gauge stainless steel. The 10 in diameter cylindrical wafer compartment has a removal lid that is sealed with a rubber gasket. The weight of the lid assures an intimate seal is made. The entire chamber rests on a 12×12 in Cimarec digital hot plate.

A freeze liquid is placed in a 250 mL gas washing bottle fitted with a porosity C fritted stopper. Nitrogen is bubbled thought the liquid and the freeze vapors are carried over the wafer in the heated reaction chamber. Gases are controlled by gas manifold valves and flow rates are monitored with a Riteflow flow meter. Unlike a prime chamber, no vacuum is used since the entire apparatus in setup in an inward airflow exhausted hood. Gases exiting the chamber are exhausted unrestricted into the rear of the hood so the overall pressure in the chamber is near atmospheric pressure.

Wafers processed through the chamber are manually placed into the chamber. The cover is placed on top and the nitrogen purge is switched to the freeze/nitrogen gas for a predetermined time after which the gas is switched back to pure nitrogen and the wafer is removed.

FIG. 2 shows the vapor reaction chamber (VRC) schematic. The chamber consists of 2 inlets, one for nitrogen purging the others for the nitrogen carrying the freeze vapors. A third port is used for exhausting. Chamber is heated with external hot plate.

### Image Hardening (Freeze) Tests

To investigate if a particular liquid was effective in freezing a photoresist a variety of test were performed.

Soak testing: This was performed by dispensing AZ ArF Thinner over the wafer until the wafer was entirely covered by a solvent puddle. After 30 seconds the wafer was spun at 500 rpm to remove the puddle while a dynamic dispense of fresh AZ ArF Thinner (PGMEA:PGME 70:30) continued to dispense for 5 seconds at the center of the wafer. Finally, the spin rate was accelerated to 1500 rpm for 20 seconds to dry the wafer. When no freeze processing is done or an inadequate freeze liquid is used the 1st photoresist imaged is entirely removed leaving only the BARC behind. For those materials that are effective in freezing the photoresist image the film thickness was compared before and after soaking in the unexposed area. No difference in the film thickness after soaking shows that freezing is sufficient for double pattern processing

CD Measurements: The critical dimensions (CD) of the photoresist pattern in the patterned areas taken before and after the soak process are also indicators if the freeze process worked. If curing is not sufficient the features may swell or dissolve.

At times the wafers which were successfully frozen were subsequently processed through a high temperature bake and/or solvent wash to test the impact of post-processing on photoresist profiles. These processes were performed on the TEL track described above. The solvent wash was AZ®ArF Thinner.

### Example 1

The hardening gases were evaluated using the imaging process described above using only AZ® AX2110P photoresist. The hardening was conducted at various hotplate temperatures for different times using the VCR and according to the process described above. The hardened photoresist image was soaked in AZ ArF thinner as described above. Prior to the hardening process the critical dimension (CD) of the first photoresist image was 38 nm. The CD was measured again after the hardening process was complete. A difference in CD before the hardening treatment and after the hardening treatment of about 8-10 nm is preferred. A large variation in the CD before and after the hardening process shows insufficient hardening which can lead to dissolution, swelling or flow of the pattern. The comparison of hardening materials is descried in Table 1.

TABLE 1
Evaluation of various hardening materials

| | | | Hardening | | |
|---|---|---|---|---|---|
| | | | Hotplate | | |
| | | Boiling | Bake | Hardening | CD (nm) after |
| | | point of | temperature | Bake time | hardening and |
| | Gas | gas (° C.) | (° C.) | (min) | solvent soak |
| 1 | 1,2-Diaminoethane | 118 | 100 | 20 | 39 |
| 2 | 1,2-Diaminoethane | 118 | 170 | 2 | 31** |
| 3 | 1,2-Diaminoethane | 118 | 190 | 2 | 81 |
| 4 | 1,2-Diaminoethane | 118 | 180 | 2 | 39 |
| 5 | 1,2-Diaminoethane | 118 | 180 | 4 | 42 |
| 6 | 1,3-Propanediamine | 140 | 180 | 2 | 39 |
| 7 | 1,3-Propanediamine | 140 | 180 | 4 | 45 |
| 8 | 1,5-Diamino-2- | 193 | 180 | 2 | 42 |
| | methylpentane | | | | |
| 9 | 1,5-Diamino-2- | 193 | 180 | 4 | 48* |
| | methylpentane | | | | |
| 10 | 1-Aminopentane | 104 | 180 | 4 | 65* |
| 11 | N-Methylbutylamine | 91 | 180 | 10 | 110* faint image |
| 12 | Triethylaamine | 89 | 180 | 10 | 100* faint image |
| 13 | Acetic acid | 117 | 180 | 10 | Image removed |
| 14 | Water | 100 | 180 | 10 | Image removed |

Initial CD 38 nm, VRC conditions, flow rate = 2500 mL/min,
*visual inspection reveals significant difference in film after soaking due to insufficient hardening, flowing or swelling.
**much of the film was removed, where patterns remained the CD was checked and was found to be smaller indicting the image is not completely frozen.

### Example 2

Hardening experiments using AZ AX 2110P alone and 1,2-Diaminoethane (DAE) hardening material are shown in the Table 2, using the same methodology as Example 1. The best hardening conditions was found to be around 1000° C. bake temperature, 20 minutes bake with a 3 L/min DAE purge rate. With these conditions photoresist films showed no sign of dissolution after soaking using the soak test as described above. Shorter hardening times are possible with higher temperatures as is evident from the Example 1.

TABLE 2
Photoresist hardening in VRC using DAE

| | | Hardening | DAE | |
|---|---|---|---|---|
| | Hardening Bake temp | Bake time | flow | |
| AZ AX2110P | (° C.) | (min) | (L/min) | Film After Soak Test |
| film | None | None | None | completely soluble |
| film | 57 | 3 | None | completely soluble |
| film | 57 | 3 | 2 | completely soluble |
| film | 57 | 20 | 2 | completely soluble |
| film | 100 | 20 | 2 | completely soluble |
| Patterned Film | 100 | 20 | 2 | completely soluble |
| Patterned Film | 100 | 20 | None | completely soluble |
| Patterned Film | 57 | 180 | 3 | only a slight indication of soak |
| | | | | line |
| Patterned Film | 57 | 180 | None | Mostly soluble |
| Patterned Film | 50 | 25 | 3 | Mostly soluble |
| Patterned Film | 100 | 60 | 3 | no indication of a soak line: |
| | | | | good hardening |
| Patterned Film | 100 | 20 | 3 | no indication of a soak line: |
| | | | | good hardening |
| Patterned Film | 100 | 5 | 3 | very slight indication of a soak |
| | | | | line |
| Patterned Film | 100 | 5 | — | Mostly soluble |
| Patterned Film | 100 | 10 | 3 | very slight indication of a soak |
| | | | | line |
| Patterned Film | 100 | 20 | 3 | no indication of a soak line: |
| | | | | good hardening |

Film coatings were prepared by spinning AZ ArF2110P photoresist at 1500 rpm and baking for 1 minute at 100° C. Patterned films were prepared the same way with the addition of a mask exposure, PEB and development as described in Example 1.

### Example 3

1^{st} Pattern Exposure AZ AX2110P was coated, exposed and developed as described above using a dose of 40 mJ at best focus. At 45 nm the DOF is about 0.2 microns. The 1st 2110P image was frozen with the VRC process using DAE at a flow rate of 3 L/min for the vapor-nitrogen gas mixture with the hotplate temperature of 100° C. for 20 minutes. In order to form the second pattern, AX210P photoresist was directly coated over the frozen image and exposed and developed with the conditions used for the first exposure except a dose of 60 mJ was used. Process margins for the second exposure were determined by top down CD SEM and were similar to the first exposure. Measurements were taken by finding the fields where the field are properly overlaid leading to the lines of the 2^{nd} exposure being interdigitated to the first exposure. Edges of the field were used so lines could easily be identified to the 1st and 2nd exposure. Cleaved SEMs revealed that the field with the proper offset exhibited at a 90 nm pitch which corresponding to 1/the pitch of the single exposures (in this example the lines from the first exposure were 60 nm and the lines from the 2^{nd} exposure were 40 nm due to the dose difference) lines from: the second exposure that were interdigitated to the 45 nm frozen lies of the first exposure, to form the correct double pattern of the second pattern being between the first pattern.

### Example 4

Double patterning imaging was achieved in a similar manner to Example 3 with the addition of a 200° C. bake after the images were processed through the VRC. Results were found to be similar as without the post hardening bake as in Example 3.

### Example 5

Double patterning imaging was achieved in a similar manner to Example 4 with the addition of a 30 second AZ ArF Thinner puddle soak after the 200° C. bake to clean the image. Results were found to be similar to Example 4.

### Example 6

Double patterning imaging was achieved in a similar manner to Example 4 except using 1,3-propylene diamine as the VRC gas. Results were found to be similar to Example 4.

### Example 7

Double patterning imaging was achieved in a similar manner to Example 4, except an exposure dose of 52 mJ/cm² was used for each exposure and the VRC chamber was used with conditions corresponding to 180° C. for 2 minutes. Results were found to be similar to Example 4 for 45 nm lines for both patterns.

1. A process for forming a photoresist pattern on a device, comprising;
a) forming a layer of first photoresist on a substrate from a first photoresist composition;
b) imagewise exposing the first photoresist;
c) developing the first photoresist to form a first photoresist pattern;
d) treating the first photoresist pattern with a hardening compound comprising at least 2 amino (NH₂) groups, thereby forming a hardened first photoresist pattern;
e) forming a second photoresist layer on the region of the substrate including the hardened first photoresist pattern from a second photoresist composition;
f) imagewise exposing the second photoresist; and,
g) developing the imagewise exposed second photoresist to form a second photoresist pattern between the first photoresist pattern, thereby providing a double photoresist pattern.

2. The process of claim 1, where the hardening compound has structure (1), 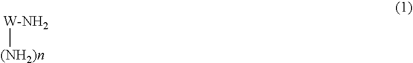
where, W is a C₁-C₈ alkylene, and n is 1-3.

3. The process of claim 1, where the hardening compound is selected from 1,2-diaminoethane, 1,3-propanediamine, and 1,5-diamino-2-methylpentane.

4. The process of claim 2, where n is 1.

5. The process of claim 1, where the treating step of the first photoresist pattern is with a vaporized hardening compound.

6. The process of claim 1, where the treating step comprises heating step.

7. The process of claim 6, where the heating step is in the range of about 80° C. to about 225° C.

8. The process of claim 1, where the first photoresist composition and the second photoresist composition are the same.

9. The process of claim 1, where the photoresists are selected from negative or positive.

10. The process of claim 1, where the first photoresist is a chemically amplified photoresist.

11. The process of claim 1, where the first photoresist composition comprises a polymer, photoacid generator and a solvent.

12. The process of claim 9, where the polymer is a (meth)acrylate polymer.

13. The process of claim 1, where after the hardening step the first photoresist is insoluble in solvent of the second photoresist composition.

14. The process of claim 1, where the loss in thickness of the first photoresist pattern in the solvent of the second photoresist is less than 10 nm.

15. The process of claim 13, where the solvent of the second photoresist composition is selected from PGMEA, PGME, ethyl lactate and mixtures thereof.

16. The process of claim 1, where the imagewise exposure is selected from 193 nm, 248 nm, 365 nm and 436 nm.

17. The process of claim 12 where the developing is with an aqueous alkaline developer.

18. The process of claim 1, further comprising a baking step after the treatment step.

19. The process of claim 1, further comprising a step of solvent cleaning the hardened pattern prior to forming the second photoresist layer.

20. A product using the process of claim 1.

21. A microelectronic device formed by using a process for forming a photoresist pattern on a device, comprising;
a) forming a layer of first photoresist on a substrate from a first photoresist composition;
b) imagewise exposing the first photoresist
c) developing the first photoresist to form a first photoresist pattern;
d) treating the first photoresist pattern with a hardening compound comprising at least 2 amino (NH₂) groups, thereby forming a hardened first photoresist pattern;
e) forming a second photoresist layer on the region of the substrate including the hardened first photoresist pattern from a second photoresist composition;
f) magewise exposing the second photoresist; and,
g) developing the imagewise exposed second photoresist to form a second photoresist pattern between the first photoresist pattern, thereby providing a double photoresist pattern.
